(19) United States
(12) Patent Application Publication
(10) Pub. No.: US 2019/0221780 A1
(43) Pub. Date: Jul. 18, 2019

(54) LIGHT EXTRACTION APPARATUS AND METHODS FOR OLED DISPLAYS AND OLED DISPLAYS USING SAME

(71) Applicant: Corning |ncorporated, Corning, NY (US)

(72) Inventors: Tomohiro Ishikawa, Corning, NY (US); Kiat Chyai Kang, Painted Post, NY (US); Dmitri Vladislavovich Kuksenkov, Elmira, NY (US); Michal Mlejnek, Big Flats, NY (US); Nikolay Timofeyevich Timofeev, St. Petersburg (RU)

(21) Appl. No.: 16/306,202

(22) PCT Filed: Jun. 2, 2017
(86) PCT No.: PCT/US2017/035636

§ 371 Date: Nov. 30, 2018

Related U.S. Application Data
(60) Provisional application No. 62/345,201, filed on Jun. 3, 2016.

(51) Int. Cl. H01L 51/52; H01L 27/32

(52) U.S. Cl. CPC H01L 51/5275; H01L 2251/5315; H01L 27/3218; H01L 27/3216

(57) ABSTRACT

Apparatus and methods for improved light extraction from top-emitting OLEDs used to form displays include an array of light-emitting apparatus (60) each having the OLED (32) and a light-extraction apparatus (64) that includes an index-matching layer (70) and a tapered reflector (51). The tapered reflector (51) has the form of an inverted truncated pyramid, with the narrow end (58) interfacing with the OLED (32) through the index-matching layer (70). Light from the OLED undergoes total internal reflection within the tapered reflector (51) at the tapered reflector side surfaces (56) and is directed toward the top surface (54) of the tapered reflector (51). This light falls within the escape cone (59) of the top surface (54) and so exits the top surface (54). The OLED display (30) has a substrate that supports an array of OLEDs (32) and also includes an array of the tapered reflectors (51) operably arranged with respect to the OLEDs (32), and an encapsulation layer (100) atop the tapered reflector array.

This application claims the benefit of priority to U.S. Application No. 62/345,201, filed Jun. 3, 2016, the content of which is incorporated herein by reference in its entirety.

### FIELD

This disclosure relates to organic light-emitting diodes (OLEDs), and in particular relates to OLED displays and apparatus and methods for light extraction from OLED displays, including OLED displays that utilize the light-extraction apparatus and methods.

### BACKGROUND

OLEDs typically include a substrate, a first electrode, one or more OLED light-emitting layers, and a second electrode. OLEDs can be top emitting or bottom emitting. A top-emitting OLED includes a substrate, a first electrode, an OLED structure having one or more OLED layers, and a second transparent electrode. The one or more OLED layers of the OLED structure includes an emission layer and can also include electron and hole injection layers and electron and hole transport layers.

A thin barrier layer typically resides atop the second electrode. The barrier layer serves to protect the OLED layers from contamination from oxygen and water. The barrier layer is typically made of high-refractive-index material, such as silicon nitride, which has a refractive index of 2.03. Since the OLED structure has a refractive index that is typically in the range 1.7 to 1.8, light emitted by the OLED structure is trapped by total internal reflection (TIR) at the top boundary (outer surface) of the barrier layer. This TIR is relatively strong (i.e., covers a relatively large range of angles) due to the large refractive index of the barrier layer relative to the material in contact with the upper surface of the barrier layer (typically air or glass).

To form a display, the OLEDs are arranged on a display substrate and covered with an encapsulation layer. However, the light emitted from the top of the OLEDs will once again be subject to TIR from the upper surface of the encapsulation layer even if the space between the encapsulation layer and the OLEDs is filled with a solid material. This further reduces the amount of OLED-generated light available for use in the OLED display.

### SUMMARY

Apparatus for and methods of light extraction for OLED displays are disclosed. The apparatus and methods utilize the fact that the OLEDs, which serve as pixels (e.g., colored pixels, also called sub-pixels) of an OLED display, are typically spaced apart and arranged in a known pattern and occupy only a relatively small portion of the top surface of the display substrate. The light-extraction apparatus and methods disclosed herein utilize an array of tapered reflectors, which can be manufactured, for example by replication, as part of the encapsulation layer such that the tapered reflectors faces have the same size and spacing as the OLEDs supported on the substrate. The tapered reflectors can then be disposed atop the OLED substrate and the OLEDs thereon using an index-matching material, which can have an adhesive property. In an example, the tapered reflectors are defined by solid prisms that operate by total internal reflection (TIR) or that have sides with a reflective coating.

An exemplary tapered reflector has the form of an inverted and truncated pyramid or cone, with the wide end of the truncated pyramid being the top where light is emitted and the narrow end being the bottom. The bottom end (bottom surface) is optically coupled to (i.e., optically interfaced with) with the light-emitting surface of the OLED. This optical coupling is preferably through the index matching material to optimize optical coupling efficiency. Preferably, both the tapered reflector material and index matching material have a relatively high refractive index, e.g., up to the refractive index of the light-emitting layer of the OLED. The combination of the OLED, the index-matching material and the tapered reflector constitute a light-emitting apparatus. The combination of the tapered reflector and the index-matching material (if employed) constitute a light-extraction apparatus.

The OLED display disclosed herein comprises a plurality or array of the light-emitting apparatus. The light-emitting apparatus can also include a portion of the encapsulation layer through which light is transmitted.

Due to TIR at the tapered reflector side walls, the light rays that otherwise fall outside of the escape cone at the top surface of the tapered reflector are re-directed by the angled or sloped sidewalls to lie within the escape cone and thus are able to out-couple from the top surface of the tapered reflector. As a result, the light extraction efficiency is improved by at least 25% or by at least 50% or by at least 100% or by at least 150% or by at least 200% as compared to when the tapered reflectors are not used.

Due to the dimensional stability of the encapsulation layer, which can be made of glass, the tapered reflectors remain aligned and securely attached to respective OLEDs within a reasonable operating/storage temperature range, e.g., from 0° C. to 60° C.

An aspect of the disclosure is a light-extraction apparatus for an OLED having a top surface through which light is emitted. The apparatus includes: a tapered reflector having a refractive index n_{P}, at least one side, a top surface and a bottom surface, with the top surface being larger than the bottom surface; an index-matching layer disposed between the top surface of the OLED and the bottom surface of the tapered reflector, and that has a refractive index n_{IM} that is equal to or larger than the tapered reflector refractive index n_{P}; and wherein the light emitted from the OLED top surface passes through the index matching layer and into the tapered reflector, and wherein the at least one side of the tapered reflector has a slope configured to redirect the light by total internal reflection into the escape cone and out of the tapered reflector top surface.

Another aspect of the disclosure is OLED display that includes: an array of the light-extracting apparatus as described above; a support substrate that supports an array of the OLEDs, wherein the OLEDs are spaced apart and operably arranged relative to the respective light-extracting devices; and an encapsulation layer that resides adjacent the top surfaces of the tapered reflectors.

Another aspect of the disclosure is a light-emitting apparatus that includes the light-extraction apparatus described above, and the OLED.

Another aspect of the disclosure is an electronics device that includes the OLED display as described above and control electronics electrically connected to the OLED display.

Another aspect of the disclosure is an OLED display that includes: a support substrate having a surface; an array of OLEDs periodically arranged on the support substrate surface, each OLED comprising a top surface to emit light; an array of tapered reflectors, each tapered reflector comprising at least one side surface, a top surface and a bottom surface, the top surface larger than the bottom surface, the bottom surface of each tapered reflector being optically coupled to a corresponding one of the array of OLEDs, the at least one side surface comprising a slope configured to totally internally reflect light from the corresponding OLED that enters the tapered reflector from the bottom surface and direct the light through the top surface of the tapered reflector; and an encapsulation layer disposed atop the top surfaces of the array of tapered reflectors to transmit the light leaving the top surface of the tapered reflector.

Another aspect of the disclosure is an electronics device that includes the OLED display as described above and control electronics electrically connected to the OLED display.

Additional features and advantages will be set forth in the following detailed description, and in part will be readily apparent to those skilled in the art from that description or recognized by practicing the embodiments as described herein, including the detailed description that follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1A is a top-down view of an example OLED display that employs the light-extraction apparatus and methods disclosed herein;

FIG. 1B is a top-down close-up view of an array of four OLEDs illustrating example dimensions of the OLEDs and the OLED array formed by the OLEDs;

FIG. 1C is a close-up x-z cross-sectional view of a section of the OLED display of FIG. 1A.

FIG. 1D is an even more close-up view of the section of the OLED display shown in FIG. 1C, and includes a close-up inset showing a basic layered OLED structure;

FIG. 2 is an elevated exploded view of an example light-emitting apparatus formed by the OLED, the index-matching material and the tapered reflector, wherein the tapered reflector and index-matching material constitute a light-extraction apparatus;

FIG. 3 is a top-down view of four OLEDs and four tapered reflectors arranged one on each OLED;

FIGS. 4A and 4B are side views of example shapes for the tapered reflectors;

FIG. 4C is a plot of an example complex surface shape for a side of the tapered reflector, wherein the shape ensures that all of the light emitted by the OLED into the body of the tapered reflector and not directly hitting the top surface is subjected to total internal reflection at the side surface of the tapered reflector;

FIG. 4D is a schematic illustration of the advantageous shape of the tapered reflector, where the shape ensures that no light rays emitted by the OLED that are outside the escape cone for the tapered reflector material can directly hit the top surface of the tapered reflector, without first being reflected by the side walls of the tapered reflector.

FIG. 5A is a schematic diagram based on a micrograph that illustrates an example red-green-blue (RGB) pixel geometry of an OLED display for a mobile phone, and showing an array of tapered reflectors arranged over the OLED pixels;

FIG. 5B is a close-up cross-sectional view of a portion of the OLED display of FIG. 5A that shows the blue and green OLED pixels, which have different sizes;

FIG. 6A is a plot of the light extraction efficiency LE (%) versus the refractive index n_{P} of a central tapered reflector in an array of tapered reflectors;

FIG. 6B is a plot of the light output LL from a first diagonal tapered reflector relative to the central tapered reflector in the array of tapered reflectors versus the refractive index n_{P} of a central tapered reflector in an array of tapered reflectors;

FIG. 6C is a plot of the light output from a neighboring tapered reflector relative to the central tapered reflector in the array of tapered reflectors versus the refractive index n_{P} of a central tapered reflector in an array of tapered reflector;

FIG. 6D is a plot of the coupling efficiency CE (%) versus the offset dX (mm) of the OLED relative to the bottom surface of the tapered reflector as measured using a large detector (diamonds) and a small detector (squares);

FIG. 7A is a plot of the calculated shear stress τₘₐₓ in the glue layer as a function of the elastic modulus E_{g} (MPa) of the glue layer for a 60° C. temperature change;

FIG. 7B is a plot of the calculated shear stress τₘₐₓ in the glue layer as a function of the elastic modulus Eₚ (MPa) of the tapered reflector material for the same 60° C. temperature change as FIG. 7A;

FIG. 8 is a plot of the light extraction efficiency LE (%) versus the refractive index nₛ of a material filling the spaces between tapered reflectors in an array of tapered reflectors;

FIGS. 9A and 9B are side views of a section of the OLED display that illustrate different configurations for the light-extraction apparatus disclosed herein;

FIG. 9C is a side view of light-extraction apparatus disclosed herein, where an additional microlens is added on top of the encapsulation layer to further aid the light extraction;

FIG. 10A is a schematic diagram of a generalized electronics device that includes the OLED display disclosed herein; and

FIGS. 10B and 10C are examples of the generalized electronics device of FIG. 10A.

### DETAILED DESCRIPTION

Reference is now made in detail to exemplary embodiments which are illustrated in the accompanying drawings. Whenever possible, the same reference numerals will be used throughout the drawings to refer to the same or like parts. The components in the drawings are not necessarily to scale, emphasis instead being placed upon illustrating the principles of the exemplary embodiments.

Cartesian coordinates are used in the Figures for the sake of reference and ease of discussion and are not intended to be limiting as to orientation or direction.

The term “light extraction” in connection with an OLED refers to apparatus and method for increasing the amount of light emitted from the OLED using features that do not reside within the actual OLED layered structure.

The unit abbreviation MPa used hereinbelow stands for “megapascal”.

The refractive index n_{O} of the OLED is an effective refractive index that includes contributions from the various layers that make up the OLED structure and in an example is in the range from 1.6 to 1.85, while in another example is in the range from 1.7 to 1.8, and in another example is in the range from 1.76 to 1.78.

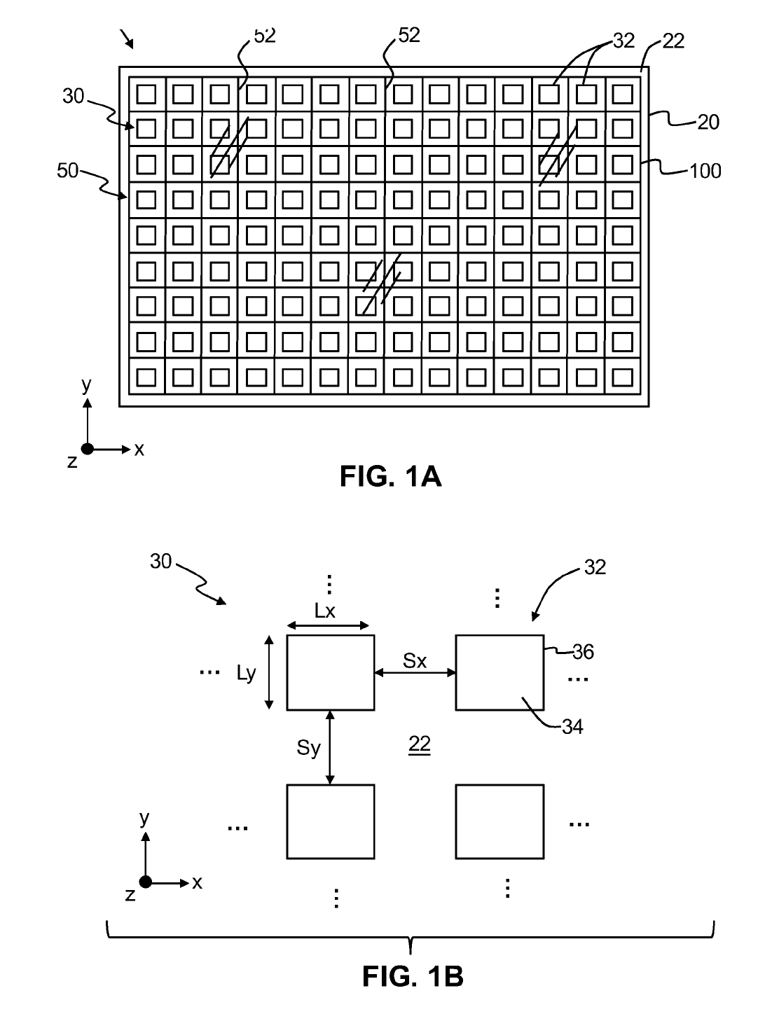

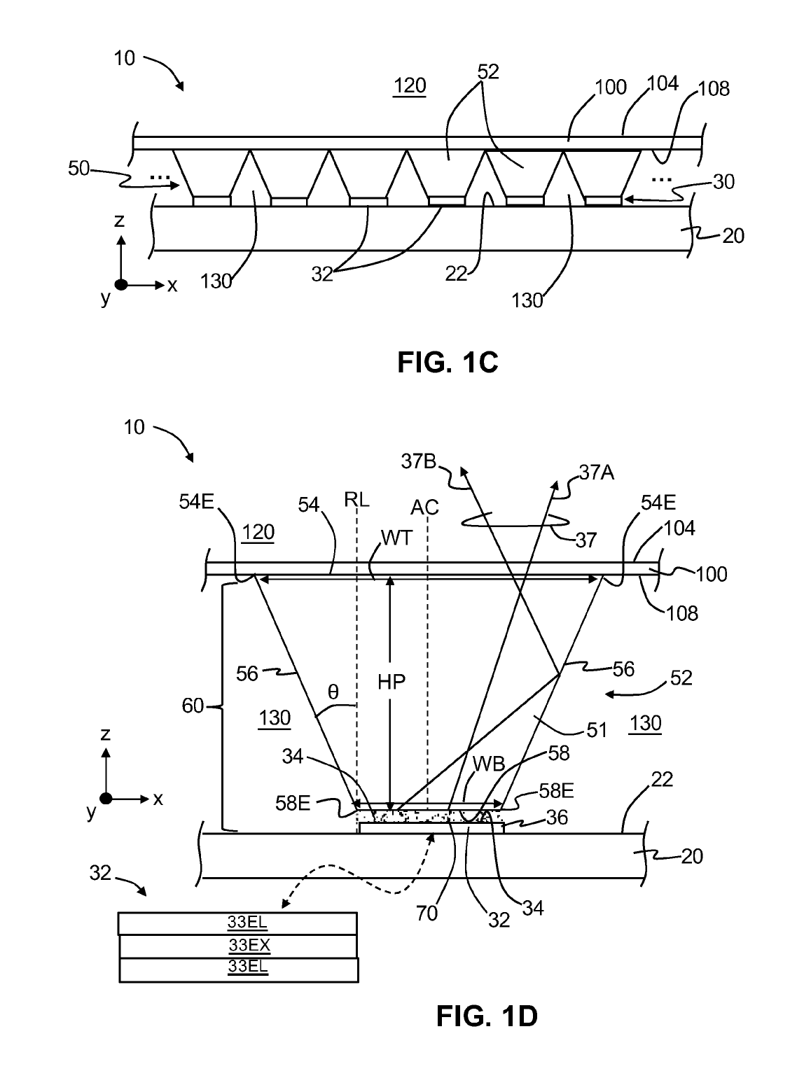

FIG. 1A is a top-down view of an example top-emitting OLED display (“OLED display”) 10 as disclosed herein. FIG. 1B is a close-up top-down view of a section of OLED display 10 while FIG. 1C is a close-up x-z cross-sectional view of a section of the OLED display. FIG. 1D is an even more close-up view of the section of OLED display 10 shown in FIG. 1C.

With reference to FIGS. 1A through 1D, the OLED display 10 includes a substrate 20 having an upper surface 22. In an example, substrate 20 is made of glass. The OLED display 10 also includes an array 30 of top-emitting OLEDs 32 that resides on upper surface 22 of substrate 20. Each OLED 32 has an upper or top surface 34 and sides 36. As shown in the close-up inset of FIG. 1D, OLED 32 includes a light-emitting layer 33EX sandwiched by electrode layers 33EL. In an example, the upper electrode layer 33EL is a substantially transparent anode while the lower electrode layer is a metal cathode. Other layers, such as electron and hole injection and transport layers, and a substrate layer, are not shown for ease of illustration.

The OLEDs 32 have a length Lx in the x-direction and a length Ly in the y-direction. In an example, Lx=Ly. The OLEDs 32 in OLED array 30 are spaced apart from each other in the x-direction and the y-direction by side-to-side spacings Sx and Sy, as best seen in the close-up inset of FIG. 1A. In an example, Sx=Sy. The OLEDs 32 emit light 37 from top surface 34. Two light rays 37A and 37B are shown and discussed below. In one example, the OLEDs 32 are all the same size and are equally spaced apart. In other example, the OLEDs do not all have the same dimensions Lx, Ly and the spacings Sx, Sy are not all the same.

The OLED display 30 further includes an array 50 of tapered reflectors 52 operably disposed respective OLEDs 32, i.e., with one tapered reflector operably disposed (i.e., optically coupled or optically interfaced) with one OLED. Each tapered reflector 52 includes a body 51, a top surface 54, at least one side surface 56 and a bottom surface 58. The top surface 54 includes at least one outer edge 54E and bottom surface 58 includes at least one outer edge 58E. The tapered reflector body 51 is made of a material having a refractive index n_{P}.

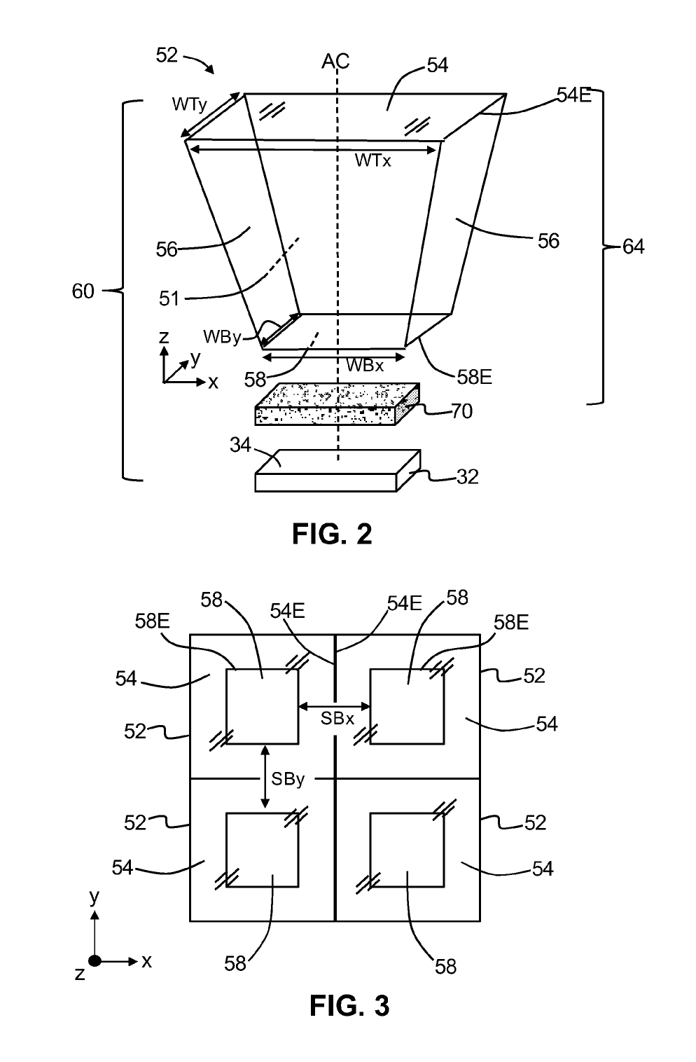

FIG. 2 is an elevated exploded view of an example light-emitting apparatus 60 formed by tapered reflector 52, an index-matching material 70 and OLED 32. The top surface 54 of tapered reflector 52 is larger (i.e., has a greater surface area) than the bottom surface 58, i.e., the top surface is the “base” of the tapered reflector. In an example, the top and bottom surfaces 54 and 58 are rectangular, e.g., square, so that there are a total of four side surfaces 56. In an example where tapered reflector 52 is rotationally symmetric, it can be said to only have one side surface 56. Side surfaces 56 can each be a single planar surfaces or made of multiple segmented planar surfaces, or be a continuously curved surfaces.

Thus, in one example, tapered reflector 52 has the form of an incomplete trapezoidal pyramid, also called an incomplete or truncated rectangular-based pyramid. Other shapes for tapered reflector 52 can also be effectively employed, as discussed below. The tapered reflector 52 has a central axis AC that runs in the z-direction. In the example where top surface 54 and bottom surface 58 have a square shape, the top surface has a width dimension WT and the bottom surface has a width dimension WB. More generally, the top surface 54 has (x,y) width dimensions WTx and WTy and bottom surface 58 has (x,y) width dimensions WBx and WBy (FIG. 2). The tapered reflector 52 also has a height HP defined as the axial distance between top and bottom surfaces 54 and 58.

As best seen in FIG. 1D, the bottom surface 58 of tapered reflector 52 is arranged on OLED 32 with bottom surface 58 residing adjacent the top surface 34 of the OLED. The index-matching material 70 has a refractive index n_{IM} and is used to interface tapered reflector 52 to OLED 32. In an example, the tapered reflector refractive index n_{P} is preferably as close as possible to the OLED refractive index n_{O}. In an example, the difference between nₚ and n_{O} is no more than 0.3, more preferably no more than 0.2, more preferably no more than 0.1, and most preferably no more than 0.01. In another example, the index-matching material refractive index n_{IM} is no lower than the tapered reflector refractive index n_{P}, and preferably has a value between nₚ and n_{O}. In an example, the tapered reflector refractive index n_{P} is between 1.6 and 1.8.

In an example, the index-matching material 70 has an adhesive property and serves to attach tapered reflector 52 to the OLED 32. In an example, index-matching material 70 comprises a glue, an adhesive, a bonding agent, or the like. As noted above, the combination of OLED 32, tapered reflector 52 and index-matching material 70 define a light-emitting apparatus 60. The tapered reflector 52 and index-matching material 70 define a light-extraction apparatus 64.

In an example, index-matching material 70 can be omitted by arranging bottom surface 58 of tapered reflector 52 to be in intimate contact with the top surface 34 of OLED 32, e.g., in optical contact.

The OLED display 10 also includes an encapsulation layer 100 that has an upper surface 104 and a lower surface 108. In an example, encapsulation layer 100 is in the form of a sheet of glass. The top surfaces 54 of tapered reflectors 52 reside immediately adjacent and in contact with the lower surface 108 of encapsulation layer 100. In an example best illustrated in FIG. 1C, the top surfaces 54 of tapered reflectors 52 tile the lower surface 108 of encapsulation layer 100 without any substantial space in between top edges 54E.

In an example, the encapsulation layer 100 and tapered reflectors 52 are formed as a unitary, monolithic structure made of a single material. This can be accomplished using a molding process or like process, such as a microreplication process using a resin-based material.

An external environment 120 exists immediately adjacent upper surface 104 of encapsulation layer 100. The external environment 120 is typically air, though it can certainly be another environment in which one might use a display, such as vacuum, inert gas, etc. FIG. 3 is similar to FIGS. 1B and 1s a top-down view that shows four OLEDs 32 and their corresponding four tapered reflectors with top surfaces 54. Note that outer edges 54E of the top surfaces 54 of adjacent tapered reflectors 52 reside immediately adjacent one another. In an example, the outer edges 54E are in contact with each other. The bottom surfaces 58 are shown as having (x,y) edge spacings between adjacent bottom-surface edges 58E of SBx and SBy, respectively. In an example, the bottom surface 58 is at least 90% of the size of the top surface 34 of OLED 32.

With reference again to FIG. 1C, the array of tapered reflectors 52 define confined spaces 130 between adjacent tapered reflectors, substrate upper surface 22 and the lower surface 108 of encapsulation layer 100. In an example, spaces 130 are filled with a medium such as air, while in other examples, the spaces are filled with a medium in the form of a dielectric material. The filling of spaces 130 with a given medium of refractive index n_{S} is discussed in greater detail below.

The tapered reflectors 52 are typically made of a material that has a relatively high refractive index, i.e., preferably as high as that of the OLED light-emissive layer 33EL. The tapered reflectors 52 are operably arranged upon corresponding OLEDs 32 in an inverted configuration using the aforementioned index-matching material 70. Each OLED 32 can be considered a pixel in OLED array 10, and each combination of OLED 32, index-matching material 70 and pyramid 50 is a light-emitting apparatus 60, with the combination of light-emitting apparatus defining an array of light emitting apparatus for OLED display 10.

Because of the relatively high refractive index n_{P} of the tapered reflectors 52 and the refractive index n_{IM} of index-matching material 70, light rays 37 generated in the OLED light-emissive layer 33EL of OLED 32 can escape from OLED top surface 34 either directly or upon being reflected by lower electrode 33EL without being trapped by TIR (FIG. 1D). After propagating through tapered reflector 52 directly to the top surface 54 (light ray 37A) or after being reflected via TIR by at least one side surface 56 (light ray 37B), the light escapes into encapsulation layer 100 and passes therethrough to external environment 120.

In an example, side surfaces 56 have a slope defined by a slope angle θ relative to the vertical, e.g., relative to a vertical reference line RL that runs parallel to central axis AC, as shown. If the slope of sides 56 is not too steep (i.e., if the slope angle θ is sufficiently large), the TIR condition will be met for any point of origin of the light rays 37 emanating from OLED top surface 34 and no light rays will be lost by passing through sides 56 and into the spaces 130 immediately adjacent the sides of tapered reflector.

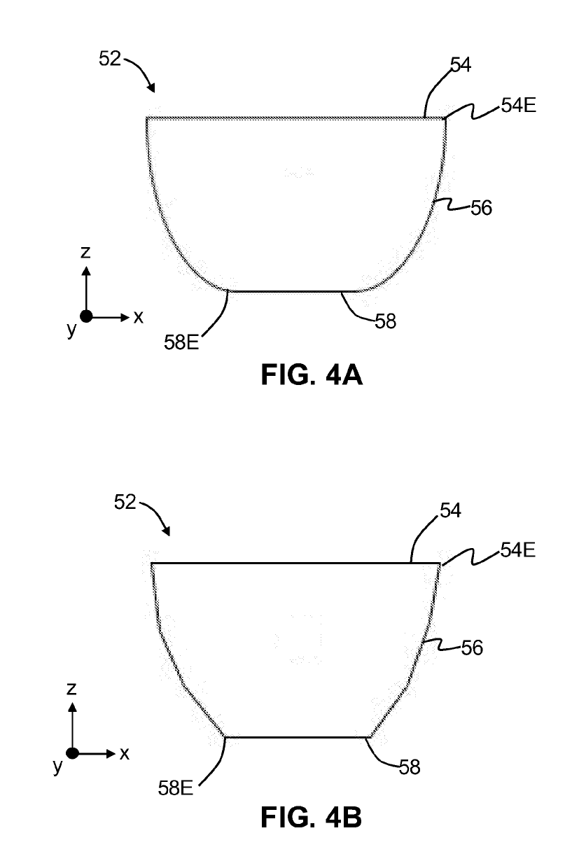

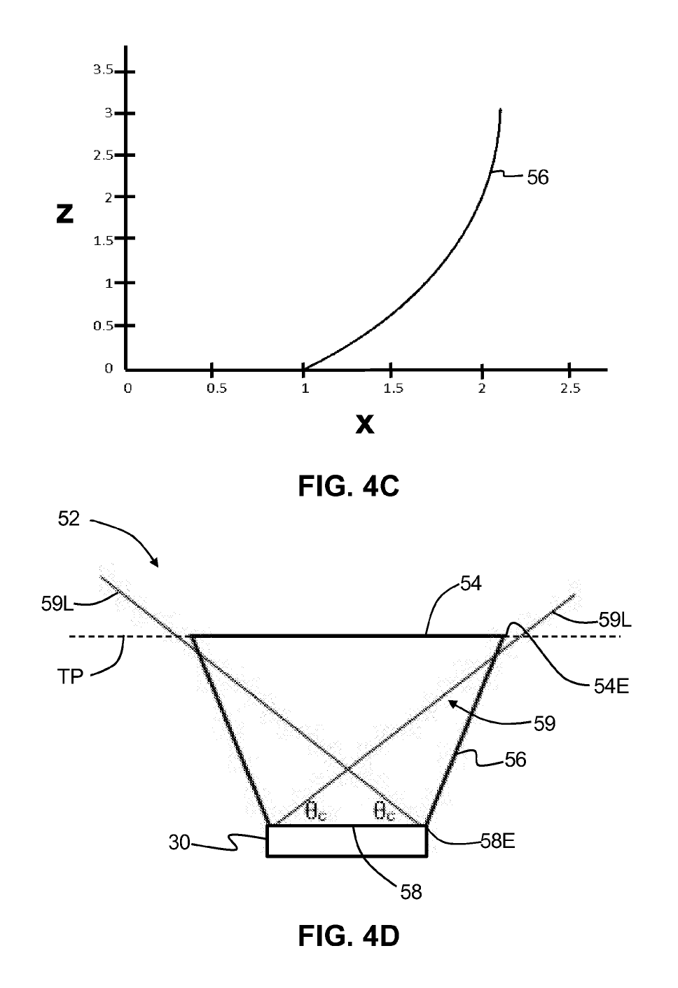

Moreover, if the height HP of tapered reflector 52 is sufficiently great, all of the light rays 37 incident upon the top surface 54 will be within a TIR escape cone 59 (FIG. 4D) defined by the refractive index n_{P} of tapered reflector 52 and the refractive index n_{E} of the encapsulation layer 100 and thus escape into the encapsulation layer. In addition, light rays 37 will also be within the TIR escape cone defined by the refractive index n_{E} of the material of encapsulation layer 100 and the refractive index nₑ of the external environment that resides immediately adjacent the upper surface 104 of the encapsulation layer.

Thus, neglecting light absorption of the otherwise transparent upper electrode 33EL in the OLED structure of OLED 32, 100% of light 37 generated by the OLED can in principle be communicated into the external environment 120 that resides above encapsulation layer 100. In essence, the index-matched material that makes up body 51 of tapered reflector 52 allows for the tapered reflector 52 to act as perfect (or near-perfect) internal light extractor while the reflective properties sides 56 allow for the tapered reflector to be a perfect (or near-perfect) external light extractor.

Explanation of TIR Conditions

At the boundary of any two dissimilar transparent materials such as air and glass having refractive indices n1 and n2, respectively, light rays incident upon the boundary from the direction of the higher-index material will experience 100% reflection at the boundary and will not be able to exit into a lower index material if they are incident at the boundary at an angle to the surface normal which is higher than a critical angle θ_{c}. The critical angle is defined by sin(θ_{c})=n1/n2.

All light rays that are able to escape the higher-index material and not be subjected to TIR therein will lay within a cone having a cone angle of 2θ_{c}. This cone is referred to as the escape cone and discussed below in connection with FIG. 4D.

It can be shown that for any sequence of layers with arbitrary refractive indices, the critical angle θ_{c} and the escape cone 59 are defined only by the refractive index of the layer where the light ray originates, and the refractive index of the layer or medium into which it escapes. Thus, an anti-reflective coating cannot be used to modify the TIR condition and cannot be used to aid light extraction by overcoming TIR conditions.

For a point source with isotropic emission into a hemisphere and the same intensity for any angle, the amount of light able to escape the source material is equal to the ratio of the solid angle of the escape cone 59 is given by 2π(1−cos(θ_{c})) and the full solid angle of the hemisphere (2π) is equal to 1−cos(θ_{c}). Taking an example of an OLED material with a refractive index n2=1.76 and air with refractive index n1=1.0, the critical angle is θ_{c}=arcsin(1/1.76)=34.62°.

The amount of light that will exit into the air for any sequence of different material layers on top of the OLED material (i.e., the light output as compared to the light input) is equal to 1−cos(34.62°)=17.7%. This is referred to as the light extraction efficiency LE. This result assumes the OLED is an isotropic emitter, but the estimate of the light extraction efficiency based on this assumption is very close to the actual result that obtains with more rigorous analysis and what is observed in practice.

Tapered Reflector Shape Considerations

The exact shape of side surfaces 56 of tapered reflector 52 is not critical for the functioning of the tapered reflector 52, as long as there is an overall tapered configuration. FIG. 4A is a side view of an example tapered reflector 52 that includes at least one curved side surface 56. FIG. 4B is a side view of an example tapered reflector 52 that includes at least one segmented planar side surfaces 56. In an example, one or more side surfaces 56 can be defined by a single curved surface, e.g., cylindrical, parabolic, hyperbolic, or any other shape besides planar, as long as tapered reflector 52 is wider at top surface 54 than at bottom surface 58. In an example, tapered reflector 52 is rotationally symmetric and so includes a single side 56.

Although not strictly required, the performance of light-emitting apparatus 60 is optimized if at any point on side surface 56 of tapered reflector 52 the TIR condition is observed for any possible point of origin of light 37 within the OLED emission layer 33EL of OLED 32. FIG. 4C is a plot of the z coordinate vs. x coordinate (relative units) for an example complex surface shape for side surface 56 calculated using a simple numerical model. The z and x axes represent normalized lengths in the respective directions. The OLED 32 is assumed to extend in the x-direction from [−1,0] to [1,0], and there is another side 56 that starts at [−1,0] location but that is not shown in the plot of FIG. 4C. The shape of side 56 was calculated such that rays originating at [−1,0] are always incident on the surface exactly at 45° to a surface normal. Any other ray originating at z=0 and x between −1 and 1 will have a higher incidence angle on side 56 than the ray originating at [−1,0].

Performance of light-emitting apparatus 60 can be further improved if the height HP of tapered reflector 52 is such that all of the light rays 37 emitted by OLED 32 exiting directly into the encapsulation layer 100 are within the escape cone 59, as illustrated in the schematic diagram of FIG. 4D. FIG. 4D includes a plane TP defined by the top surface 54 of tapered reflector 52. The condition is met when top surface 54 of tapered reflector 52 is entirely within (i.e., not intersected by) the lines 59L that define the limits of the escape cone 59. The escape cone lines 59L originate at the edges 58E of bottom surface 58 and intersect plane TP at the critical angle θ_{c} with respect to top surface 54, where the value of θ_{c} is defined by the refractive index of the tapered reflector material nₚ and air nₐ as sin(θ_{c})=nₐ/nₚ.

In a general case, there exists an optimum height HP of the tapered reflector 52 that depends on the geometry (size of and spacing between) OLEDs 32 and the refractive index nₚ of tapered reflectors 52. If the height HP is too small, all light rays 37 emitted from the OLEDs 32 will undergo TIR at the side surfaces 56 of the tapered reflector 52, but some rays will go directly to the top surface 54 and be incident thereon at an angle larger than the critical angle and therefore will be trapped at the first boundary with air in the display. If the height HP is too large, all light rays 37 going directly to the top surface 54 will be within the escape cone 59, but some light rays falling on the side surfaces 56 will be within the escape cone for the side surfaces and thus exit the side surfaces. In an example, the optimum height HP of the tapered reflectors HP is typically between (0.5)WB and 2WT, more typically between WB and WT. Also in an example, the local slope of the side walls 56 can be between 2° and 50°, or even between 10° and 45°.

Tapered Reflector Array

As noted above, the plurality of tapered reflectors 52 define a tapered reflector array 50. The bottom surfaces 58 of the tapered reflectors 52 are respectively aligned with and optically coupled to top surfaces 34 of OLEDs 32. Since the top surfaces 54 of tapered reflectors 52 are larger than the bottom surfaces 58, in one example (see FIG. 1C) the top surfaces are sized to cover substantially the entire lower surface 108 of encapsulation layer 100 of the encapsulation glass, or as close as the specific manufacturing technique employed allows.

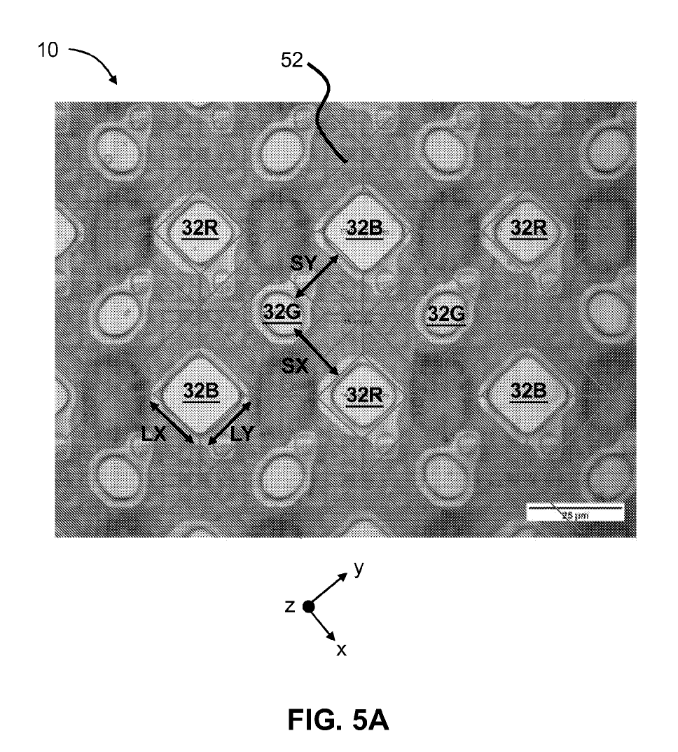

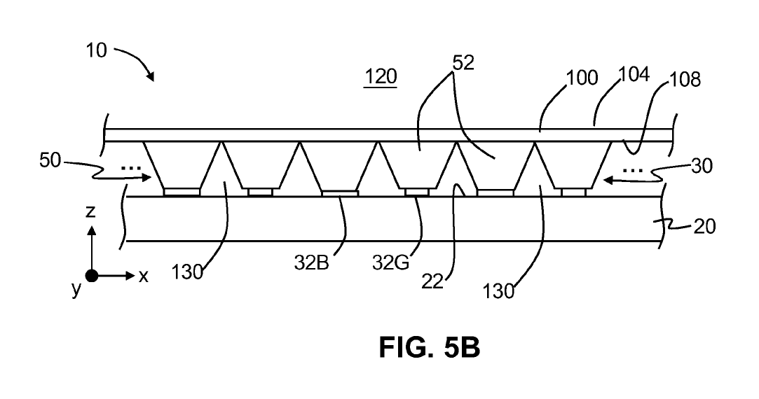

FIG. 5A is a schematic diagram based on a micrograph that illustrates an example red-green-blue (RGB) pixel geometry of an OLED display 10 for a mobile phone. FIG. 5B is a cross-sectional view of a portion of the OLED display 10 that show green OLEDS 32G and blue OLEDS 32B. The pixels are defined by OLEDs 32 arranged in a diamond pattern, so that the OLEDs are also referred to as OLED pixels. The x- and y-axes can be considered as rotated clockwise by 45°, as shown in FIG. 5A.

The OLEDs 32 emit colored light and are denoted 32R, 32G and 32B for red, green and blue light emission, respectively. The solid lines depict the contours of the eight tapered reflectors 52 associated with the eight colored OLEDs 32 shown. The top surfaces 54 of tapered reflectors 52 are touching each other while the bottom surfaces 58 fully cover their respective OLED 32R, 32G and 32B. Since green OLEDs 32G are smaller than the blue OLEDs 32B and yet a perfectly periodic array is preferable, the bottom surfaces 58 of the respective tapered reflectors 52 are sized to the blue OLEDs and are slightly oversized with respect to the green OLEDs.

In another example, the configuration of array 50 of tapered reflectors 52 is configured to match the configuration of the array 30 of OLEDs. Thus, in an example the tapered reflectors 52 do not all have the same dimensions WBx, WBy and do not all have the same bottom-edge spacings SBx, SBy.

The example OLED display 10 can be thought of as having solid material layer residing immediately above OLEDs 32 with a thickness equal to the height HP of tapered reflectors 52 and with a rectangular grid of intersecting V-groove spaces 130 cut into the solid material layer. Such a structure can be microreplicated in a layer of suitable resin or a photocurable or thermally curable material, with a master replication tool configured to define a rectangular grid of triangular cross-section ridges. Such a tool, for example, can be manufactured by first diamond machining the pattern that looks exactly like the tapered reflector array, and then making a master by replicating an inverse pattern. The master can be metalized for durability.

As shown in FIG. 5A and FIG. 5B, in an example, the spacing Sx and Sy between the colored OLEDS 32R, 32G and 32B is approximately equal to the size Lx, Ly of the largest OLED (i.e., the blue OLED 32B). If the tapered reflector top surface 54 is twice as large as the bottom surface 58, and the height HP of the tapered reflector is 1.5 times as tall as the bottom surface is wide, and the side walls are flat, then the slope angle θ of side surface 56 is arctan(⅓)=18.4°. Manufacturing tapered reflector 52 or an array 50 of tapered reflector 52 having this slope angle is within the capability of diamond machining technology.

If the bottoms of the V-grooves are more rounded, then for the same slope angle θ, the height HP of tapered reflector 52 can be smaller than 1.5 times the size (dimension) of the bottom surface 58. For a different configuration of OLED display 10, or a different technique for making the replication masters, different restrictions on the geometry of the tapered reflectors may apply.

As explained above, to form a periodic array 50 of tapered reflectors 52, the replication tool or mold is a negative replica of the structure, which might be considered to be an array of truncated depressions or “bowls”. When using such tool for forming tapered reflector array 50, it may be preferred to avoid trapping air in the bowls when the tool is pressed into a layer of liquid or moldable replication material. One technique to avoid such air trapping is to manufacture a replication tool or mold as an array of complete and not truncated pyramidal bowls. In this case, the height of the tapered reflectors can be controlled by the thickness of the replication material layer. The tool is pressed in the replication material until in comes in contact with glass substrate 20. Air pockets will be left above each of the replicated tapered reflectors on purpose. Care can be taken to avoid rounding of the tapered reflector tops by surface tension.

Light Extraction Efficiency

To estimate the light extraction efficiency of the tapered reflectors 52 in OLED display 10, ray tracing was performed using standard optical design software for a modeled OLED display. A 5×5 array 50 of tapered reflectors 52 was considered. Each tapered reflector 52 had a bottom surface size of 2×2 units, a top surface size of 4×4 units and a height HP of 3 units. These dimensionless units are sometimes called “lens units” and are used when the modeling results scale linearly. The tapered reflectors 52 were sandwiched between two pieces of glass each with a refractive index of 1.51. Immediately under the bottom surface 58 of each tapered reflector 52 was placed a very thin layer of a material with a refractive index of 1.76. This thin layer serves the role of the OLED and so is referred to as the OLED layer. The uppermost piece of glass served as the encapsulation layer 100 of the OLED display 10.

The bottom surface of the OLED layer was set to be perfectly reflective to represent a reflective bottom electrode 33EL A source of light was placed within the OLED layer and only under the central tapered reflector 52 in the 5×5 array. The light source was isotropic (i.e., uniform intensity versus angle) and had the same transverse dimensions as the bottom surface 58 of tapered reflector 52. The light output from the top (encapsulation) layer was then calculated. Modeling of the light emission from the modeled OLED display was carried out with and without the tapered reflectors 50 to determine the light emission efficiency LE. The light output was determined by select placement of virtual detectors.

Without the array 50 of tapered reflectors 52, the light output was about 16.8% of the source output, which is very close to the 17.7% value calculated above based on a simplified calculation of the size of the escape cone.

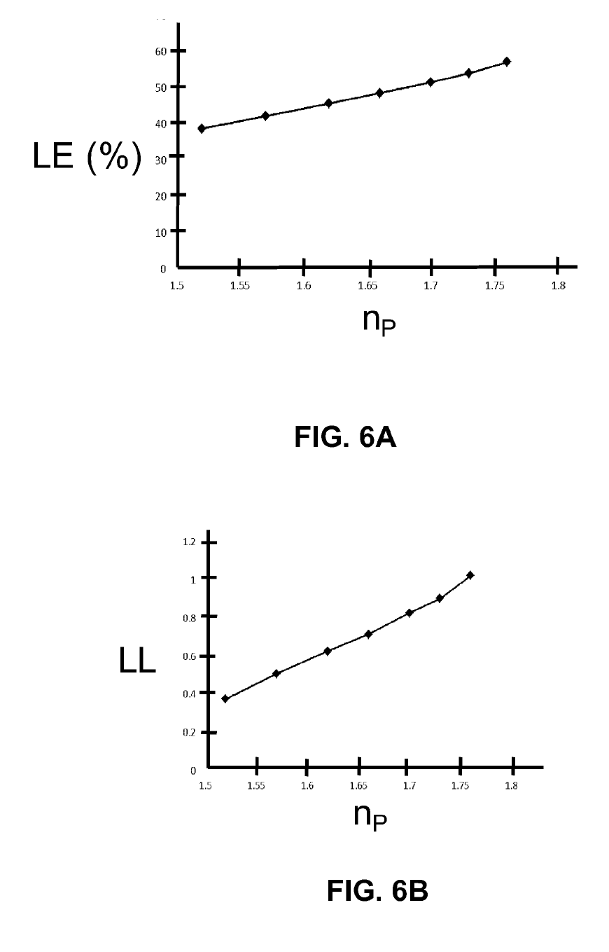

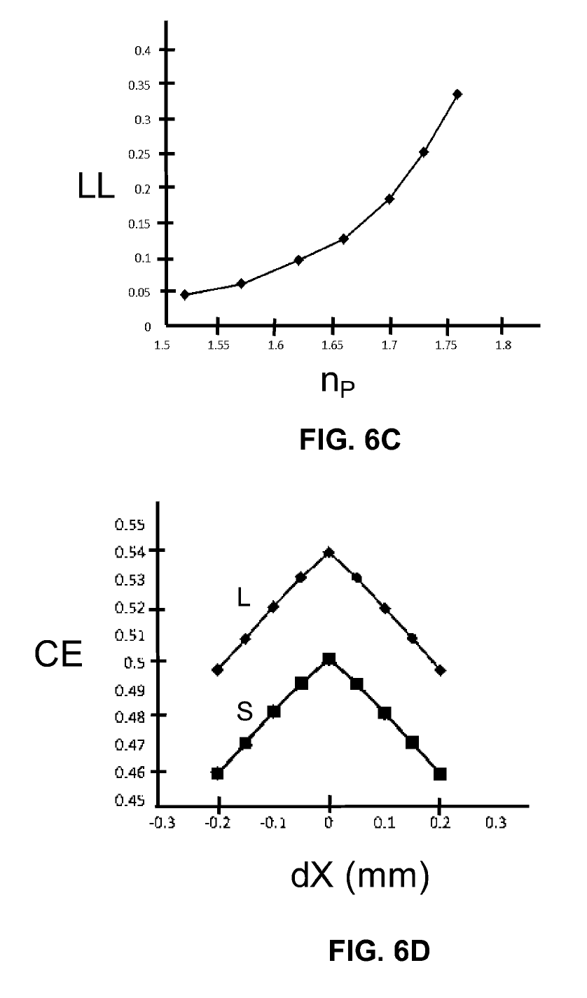

The light-extraction efficiency LE (%) with tapered reflectors 52 are shown in the plots of FIGS. 6A through 6C. The horizontal axis is the refractive index n_{P} of the tapered reflectors. In FIG. 6A, the vertical axis is the light extraction efficiency LE (%). It is noted that there is some light spillover to the adjacent tapered reflectors 52. The power out of each tapered reflector 52 in tapered reflector array 50 is easily estimated in the model by placing a small rectangular (virtual) detector at top surface 54 of the given tapered reflector. For simplicity, the light extraction efficiency LE (%) is defined here as the power out of the central tapered reflector divided by the total power emitted by the light source.

As can be seen from FIG. 6A, light extraction efficiency LE reaches 57.2%, or 3.2 times (220%) higher than 17.7%, if the refractive index n_{P} of the tapered reflector matches that of the OLED layer, namely 1.76. However, even for n_{P}=1.62, the light extraction efficiency LE is improved by 2.57× (i.e., 157%), that is, from 17.7% to 45.8%. This does not take into account the “focusing” effect due to the tapered shape of tapered reflector 52, so the gain in brightness in the normal direction might be even slightly higher, depending on the details of OLED structure and the precise shape and height of the tapered reflectors.

In various examples, the light-extraction efficiency LE is greater than 15% or greater than 20% or greater than 25% or greater than 30% or greater than 40% or greater than 50%, depending on the various parameters and configuration of the components of light-emitting apparatus 60.

With reference again to FIGS. 5A and 5B, in case of the diamond arrangement for the OLED display 10, for the green OLEDs 32G, the nearest neighbor of the same color is under the next diagonal tapered reflector and for the blue and red OLEDS 32B and 32R, the nearest neighbor of the same color is under the second tapered reflector to any of the four sides. The light leakage LL, which is defined as the light output of side tapered reflectors divided by the light output of the central one, is plotted in FIG. 6B and in FIG. 6C, also as a function of the tapered reflector refractive index n_{P}. FIG. 6B is for the closest diagonal tapered reflector 52 while FIG. 6C is for the second neighboring tapered reflector to the right of the central tapered reflector. As is evident from the FIG. 6B, the light leakage to the next tapered reflector associated with the same color OLED is only about 0.6% for the green OLED 32G and 0.2% for blue and red OLEDS 32B and 32R, for the same tapered reflector material with n_{P}=of 1.62.

The modeling as described above was performed using principles of geometrical optics and so does not take into account other effects better described by wave optics. The geometric-optics model also does not take into account effects that are internal to OLED 32. Taking these other factors into account is expected to only slightly increases the calculated light emission efficiency and only affects internal light extraction, i.e., extracting light from within the OLED structure so that more exits the OLED top surface 34. The apparatus and methods disclosed herein are directed to light extraction, i.e., extracting light using structures that are external to OLED 32.

The improved light-emission apparatus and methods disclosed herein rely entirely on light reflection and not light scattering. Thus, the polarization of ambient light reflected by a reflective electrode 33EL is unchanged upon reflection, which means that the approach is perfectly compatible with the use of circular polarizers. Also, there is no haze in reflection and therefore no decrease of the display contrast ratio, which is a problem characteristic of almost all other approaches to improving light extraction using scattering techniques.

Alignment Considerations

All of the light extraction efficiency values quoted above assumed perfect alignment between the OLED 32 source and bottom surface 58 of tapered reflector 52. The same type of modeling as used above was also used to estimate the sensitivity to misalignment between OLED 32 and tapered reflector 52. FIG. 6D plots the coupling efficiency CE versus an x-offset dX (mm) for the case where refractive index n_{P} of the tapered reflector is the same as that of OLED 32.

The results show that the output power (and therefore the coupling efficiency CE) scales linearly with offset dX, with an offset of 10% causing about an 8% drop in light output. The virtual detectors in the model were placed at the outer surface of the encapsulation glass (boundary with air). In FIG. 6D, the curve S is for a “small detector” and refers to a virtual detector the same size as the top of the tapered reflector. Likewise, the curve L is for a “large detector” and refers to a slightly larger virtual detector designed to capture all rays exiting the tapered reflector on top of the emitting OLED.

Modeling was also carried out for a 10×10 array 50 of tapered reflectors 52 to estimate a possible decrease in sharpness or contrast ratio of the OLED display 10 caused by the light leakage to neighboring tapered reflectors. The modeling indicated that such light leakage did not have a substantial impact on the contrast ratio.

CTE Mismatch Considerations

In conventional OLED displays, the coefficient of thermal expansion (CTE) of the encapsulation layer is the same or very similar to that of OLED glass substrate. However, the CTE of tapered reflectors 52 can be substantially different, especially in the case when the tapered reflectors are formed using a polymer or a hybrid (organic with inorganic filler) resin.

A simple estimate of the magnitude of mechanical stress that will be induced in light-emitting apparatus 60 as the environment temperature changes was performed using the approach described in the publication by W. T. Chen and C. W. Nelson, entitled “Thermal stress in bonded joints,” IBM Journal of Research and Development, Vol. 23, No. 2, pp. 179-188 (1979)(hereinafter, “the IBM publication”), which is incorporated herein by reference.

The light-emitting apparatus 60 of FIG. 1D was modeled as a three-layer system of a tapered reflector 52 made of a resin, an index-matching material 70 in the form of a glue layer, and an OLED 32 made of glass. The maximum shear stress τₘₐₓ in the glue layer 70 was calculated using the following equations from the IBM publication:

$${τ}_{max} = \frac{( {α}_{1} - {α}_{2} ) Δ TG tanh ( β l )}{β t}$$

$$β = {[ \frac{G}{t} ( \frac{1}{{E}_{1} {h}_{1}} + \frac{1}{{E}_{2} {h}_{2}} ) ]}^{\frac{1}{2}}$$

where G is the shear modulus of the glue layer, I is the maximum bond dimension from center to edge (half diagonal in case of a square sub-pixel and tapered reflector bottom), t is the thickness of the glue layer, α₁ and α₂ are the coefficients of thermal expansion of the bonded materials (i.e., for the resin of tapered reflector and for glass, in units of ppm/° C.), ΔT is the change in temperature (° C.), E₁ and E₂ are the Young's moduli and the h₁ and h₂ are the thickness of the bonded materials, i.e., the resin and glass, respectively. Note that h₁ is the same as the tapered reflector height HP.

The calculations assumed that the bottom surface 58 of tapered reflector 52 had dimensions of 16×16 μm, and also assuming that I=11.3 μm and t=2 μm, the height of the tapered reflector HP=h₁=24 μm, and taking α₁−α₂=70 ppm/° C., ΔT=60° C., and a Poisson ratio of the glue of 0.33 (typical for epoxies).

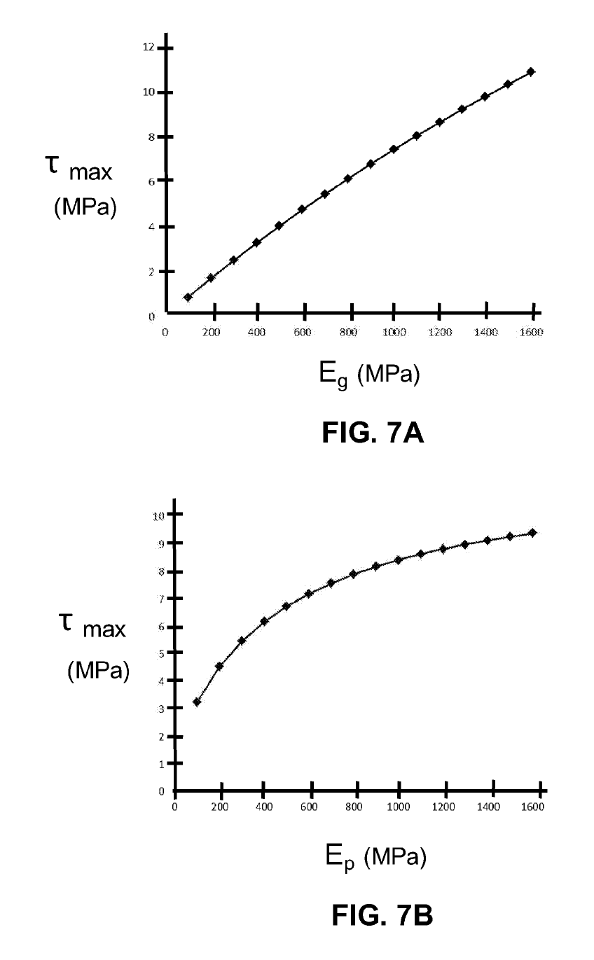

FIG. 7A is a plot of the calculated shear stress τₘₐₓ in the glue layer 70 as a function of the elastic modulus E_{g} (MPa) of the glue layer for a 60° C. temperature change, while FIG. 7B is a plot of the calculated shear stress τₘₐₓ in the glue layer 70 as a function of the elastic modulus Eₚ (MPa) of the resin material of the tapered reflector, for the same 60° C. temperature change. The shear modulus G values were calculated from elastic modulus Eₚ and the Poisson ratio v using G=Eₚ/(2(1+v)). The calculated values of the shear stress τₘₐₓ in the glue layer 70 range from 1 to 11 MPa. There are many commercially available glues having a shear strength higher than 11 MPa. In addition, a 60° C. temperature swing is quite extreme, consider that if the zero stress point is at room temperature of 20° C., this would mean taking the device to either −40° C. or 80° C.

It is generally considered beneficial to minimize possible temperature induced stress because temperature cycling can cause a gradual failure of the device. The results shown in FIGS. 7A and 7B suggest that this can be achieved by lowering the elastic modulus of the material used to form the truncated prims and/or by using a softer glue (i.e., one with a lower elastic modulus).

Resin Tapered Reflectors

As noted above, in an example the array 50 of tapered reflectors 52 can be formed using a resin since resins are amenable to molding processes and like mass-replication techniques. When forming the array 50 using a resin, it is preferred that edges of encapsulation layer 100 be free of resin so that it can be coated by a frit for edge sealing. In addition, it is preferred that the resin be able to survive a 150° C. processing temperature typical of making touch sensors. Also, it is preferred that the resin exhibit no or extremely low outgassing within the operating temperature range, at least of the type most detrimental for OLED materials, namely oxygen and water.

Material for the Spaces Between the Tapered Reflectors

As noted above, the array 50 of tapered reflectors 52, the OLEDs 32 and encapsulation layer 100 define confined spaces 130 filled with a medium having a refractive index n_{S}. In an example, the confined spaces 130 are filled with air, which has a refractive index of n_{S}=nₐ=1. In other examples, spaces 130 can be filled with a solid material. It is generally preferred that the medium within spaces 130 has as low a refractive index as possible so that escape cone 59 stays as large as possible.

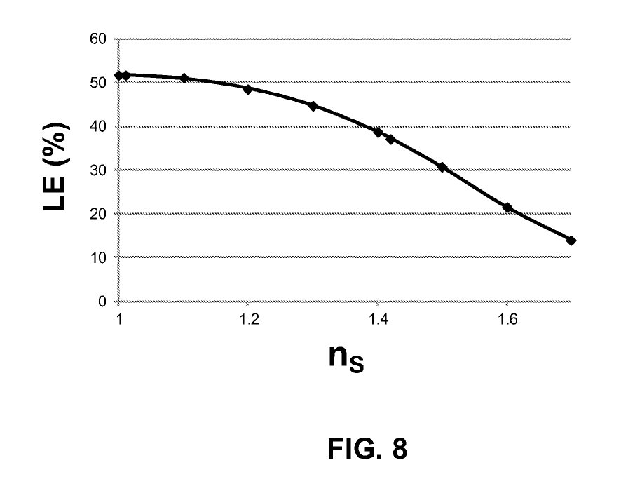

FIG. 8 is a plot of the light extraction efficiency LE (%) versus the index of refraction n_{S} of the material that fills spaces 130, assuming a refractive index n_{P}=1.7 for tapered reflector 52. The plot shows a greater than 2× (100%) improvement in light extraction efficiency (as compared to not using tapered reflector 52) even when the index n_{S} of the filler material for spaces 130 is as high as 1.42, which is a typical value for silicone adhesives.

To achieve the best possible light extraction benefit, it is preferable that the index n_{S} of the filler material be 1.2 or smaller. An example of a material with such a low refractive index is aerogel, which is porous organic or inorganic matrix filled with air or other suitable dry and oxygen-free gas. A silica-based aerogel can also serve an additional role of absorbing any residual water contamination, increasing the lifetime of the OLED materials.

If the material making up the body 51 of tapered reflector has a refractive index n_{P} of 1.7 and the refractive index of aerogel is 1.2, then the critical angle θ_{c} will be about 45°, which is an acceptable critical angle.

Tapered Reflector Modifications

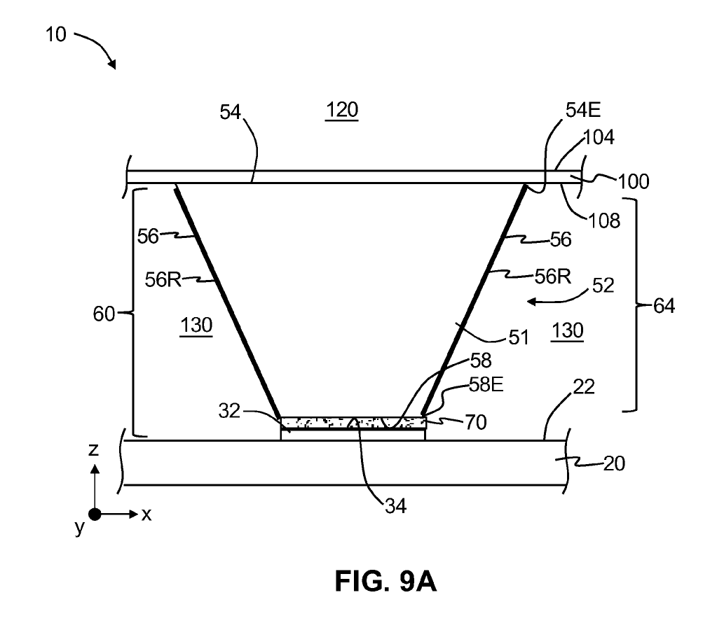

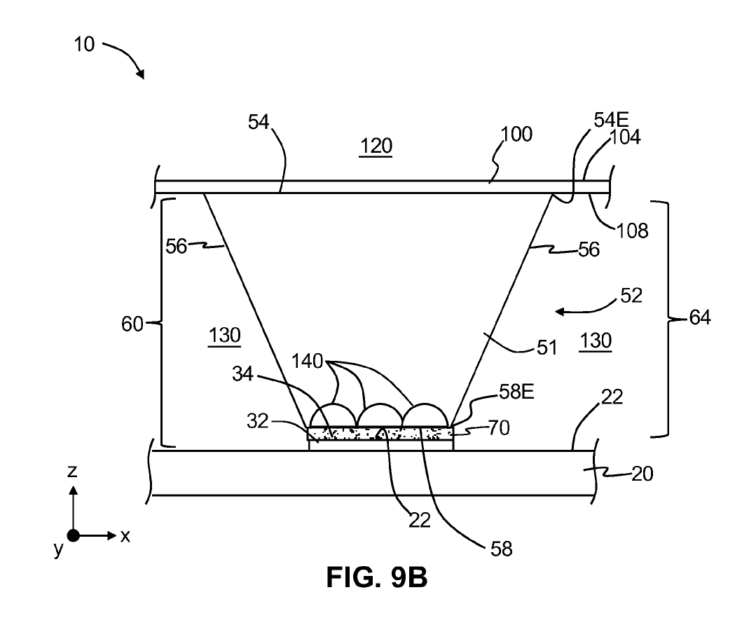

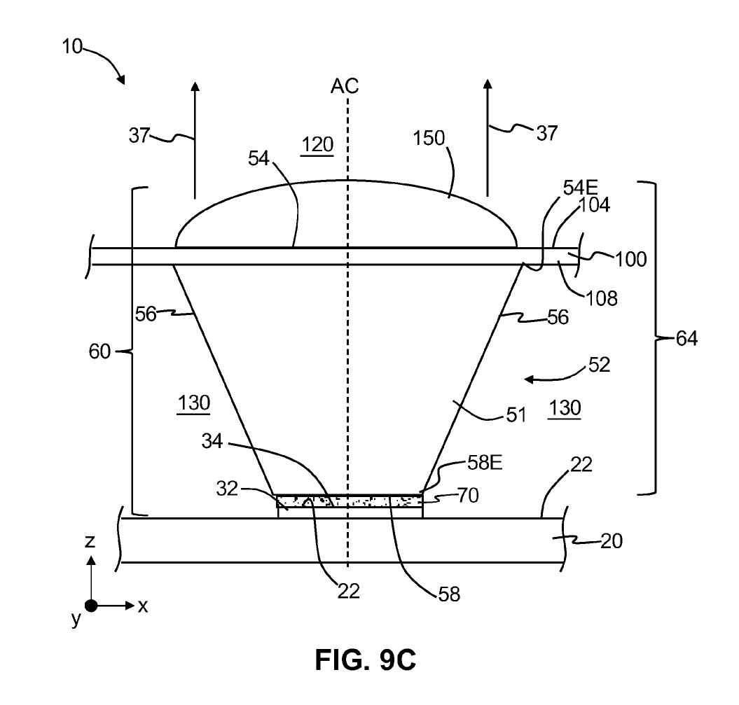

The tapered reflectors 52 can be modified in a number of ways to enhance the overall light extraction efficiency. For example, with reference to FIG. 9A, in one embodiment side surfaces 56 can include a reflective coating 56R. This configuration allows for essentially any transparent material to fill spaces 130 since the tapered reflectors no longer operate using TIR.

Another modification is illustrated in the side view of FIG. 9B, which shows microlenses 140 formed on the bottom surface 58 of the tapered reflector and that extend into the body 51 of the tapered reflector. The microlenses 140 have a refractive index n_{M} that is higher than the refractive index n_{P} of the body of the tapered reflector. The structure shown in FIG. 9B can be created by forming tapered reflector with recesses (e.g., hemispherical, aspherical, etc.) at bottom surface 58 and then filling the recess with a high-refractive-index material.

FIG. 9C shows an example embodiment where a lens element 150 is added to the upper surface 104 of encapsulation layer 100 above tapered reflector 52, i.e., along the central axis AC. The lens element 150 can be configured to provide additional collimation for light 37 exiting the encapsulation layer. In an example, lens element 150 is considered part of light-emitting apparatus 60 as well as light-extraction apparatus 64

Electronics Devices Utilizing the OLED Display

The OLED displays disclosed herein can be used for a variety of applications including, for example, in consumer or commercial electronic devices that utilize a display. Example electronic devices include computer monitors, automated teller machines (ATMs), portable electronic devices including, for example, mobile telephones, personal media players, and tablet/laptop computers. Other electronic devices include automotive displays, appliance displays, machinery displays, etc. In various embodiments, the electronic devices can include consumer electronic devices such as smartphones, tablet/laptop computers, personal computers, computer displays, ultrabooks, televisions, and cameras.

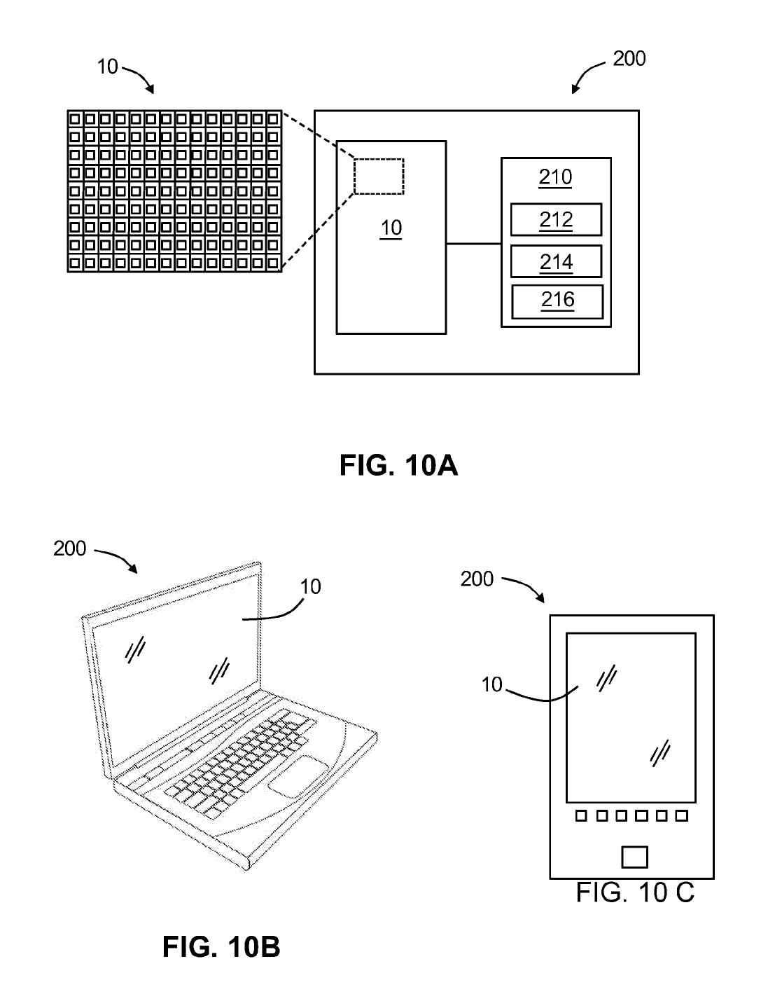

FIG. 10A is a schematic diagram of a generalized electronics device 200 that includes OLED display 10 as disclosed herein. The generalized electronics device 200 also includes control electronics 210 electrically connected to OLED display 10. The control electronics 210 can include a memory 212, a processor 214 and a chipset 216. The control electronics 210 can also include other known components that are not shown for ease of illustration.

FIG. 10B is an elevated view of an example electronics device 200 in the form of a laptop computer. FIG. 10C is a front-on view of an example electronics device 200 in the form of a smart phone.

It will be apparent to those skilled in the art that various modifications and variations can be made without departing from the spirit or scope of the disclosure. Accordingly, the disclosure is not to be restricted except in light of the attached claims and their equivalents.

1. A light-extraction apparatus for an organic light-emitting diode (OLED) having a top surface through which light is emitted, comprising:
a tapered reflector comprising a refractive index n_{P}, at least one side, a top surface and a bottom surface, the top surface being larger than the bottom surface;
an index-matching layer disposed between the top surface of the OLED and the bottom surface of the tapered reflector and comprising a refractive index n_{IM} that is greater than or equal to the tapered reflector refractive index n_{P}; and
wherein the light emitted from the OLED top surface passes through the index matching layer and into the tapered reflector, and wherein the at least one side of the tapered reflector has a slope configured to redirect the light by total internal reflection into an escape cone of the tapered reflector and out of the tapered reflector top surface.

2. The light-extraction apparatus according to claim 1, wherein the tapered reflector has the form of a truncated trapezoidal pyramid.

3. The light-extraction apparatus according to claim 1, wherein the device has a light-extraction efficiency that is greater than 10%.

4. The light-extraction apparatus according to claim 1, wherein the device has a light-extraction efficiency that is greater than 25%.

5. The light-extraction apparatus according to claim 1, wherein the device has a light-extraction efficiency that is greater than 50%.

6. The light-extraction apparatus according to claim 1, wherein the tapered reflector is made of a resin.

7. The light-extraction apparatus according to claim 1, wherein the light from the OLED is either red, green or blue light.

8. The light-extraction apparatus according to claim 1, wherein the at least one side of the tapered reflector interfaces with a medium having a refractive index n_{S} of 1.2 or smaller.

9. The light-extraction apparatus according to claim 1, further including at least one microlens of refractive index n_{M}>n_{P} embedded in the tapered reflector at the bottom surface of the tapered reflector.

10. The light-extraction apparatus according to claim 1, further including a collimating lens disposed adjacent the top surface of the tapered reflector.

11. The light-extraction apparatus according to claim 1, wherein the OLED has a refractive index n_{O} and wherein the difference between the tapered reflector refractive index n_{P} and the OLED refractive index n_{O} is less than 0.3.

12. The light-extraction apparatus according to claim 1, wherein the OLED has a refractive index n_{O} and wherein the difference between the tapered reflector refractive index n_{P} and the OLED refractive index n_{O} is less than 0.2.

13. The light-extraction apparatus according to claim 1, wherein the OLED has a top surface and wherein the bottom surface of the tapered reflector has a size that is at least 90% of the size of the OLED top surface.

14. An OLED display, comprising:
an array of the light-extracting apparatus according to claim 1;
a support substrate that supports an array of the OLEDs, wherein the OLEDs are spaced apart and operably arranged relative to the respective light-extracting devices; and
an encapsulation layer that resides adjacent the top surfaces of the tapered reflectors.

15. The OLED display according to claim 14, wherein each top surface of each tapered reflector includes an outer edge, and wherein the outer edges of adjacent tapered reflectors reside immediately adjacent one another, and wherein the top surfaces are in contact with a lower surface of the encapsulation layer.

16. The OLED display according to claim 14, wherein each OLED in the array of OLEDs has the same dimensions.

17. The OLED display according to claim 14, wherein the OLEDs in the array of OLEDs have the same edge spacing.

18. A light-emitting apparatus, comprising:
the light-extraction apparatus according to claim 14; and
the OLED.

19. An electronic device comprising:
the OLED display according to claim 14; and
control electronics electrically connected to the OLED display.

20. An organic light-emitting diode (OLED) display comprising:
a support substrate having a surface;
an array of OLEDs periodically arranged on the support substrate surface, each OLED comprising a top surface to emit light;
an array of tapered reflectors, each tapered reflector comprising at least one side surface, a top surface and a bottom surface, the top surface larger than the bottom surface, the bottom surface of each tapered reflector being optically coupled to a corresponding one of the array of OLEDs, the at least one side surface comprising a slope configured to totally internally reflect light from the corresponding OLED that enters the tapered reflector from the bottom surface and direct the light through the top surface of the tapered reflector; and
an encapsulation layer disposed atop the top surfaces of the array of tapered reflectors to transmit the light leaving the top surface of the tapered reflector.

21. The OLED display according to claim 20, wherein the array of tapered reflectors and the encapsulation layer are formed from a single material as a monolithic structure.

22. The OLED display according to claim 20, wherein the array of tapered reflectors comprises a microreplicated resin disposed on the encapsulation layer.

23. The OLED display according to claim 20, further comprising an index matching layer operably disposed between the top surface of each OLED and the bottom surface of the corresponding tapered reflector optically coupled thereto.

24. The OLED display according to claim 20, wherein each tapered reflector in the array of tapered reflectors has the form of a truncated trapezoidal pyramid.

25. OLED display according to claim 20, wherein each tapered reflector top surface has an outer edge and wherein the outer edges of adjacent tapered reflectors reside immediately adjacent one another.

26. The OLED display according to claim 25, wherein the tapered reflector top surfaces are in contact with a lower surface of the encapsulation layer.

27. The OLED display according to claim 20, wherein the display has a light-extraction efficiency of 20% or greater.

28. The OLED display according to claim 20, wherein the array of tapered reflectors define spaces between adjacent side surfaces of tapered reflectors so that the at least one side surface of each tapered reflector interfaces with a medium within the spaces having a refractive index n_{S} that is in the range between 1 and 1.2.

29. The OLED display according to claim 20, wherein the tapered reflector refractive index n_{P} is in the range from 1.6 to 1.8

30. The OLED display according to claim 20, wherein the OLED top surface has a first size and the bottom surface of the tapered reflector has a second size that at least as large as the first size.
